(19) United States
(12) Patent Application Publication
(10) Pub. No.: US 2005/0199884 A1
(43) Pub. Date: Sep. 15, 2005

(54) High power LED package

(75) Inventors: Seon Goo Lee, Gunpo (KR); Seung Mo Park, Seoul (KR); Chan Wang Park, Sungnam (KR); Jung Kyu Park, Suwon (KR)

Correspondence Address: LOWE HAUPTMAN GILMAN AND BERNER, LLP, 1700 DIAGONAL ROAD, SUITE 300 /310, ALEXANDRIA, VA, 22314, US

(73) Assignee: Samsung Electro-Mechanics Co., Ltd., Suwon (KR)

(21) Appl. No.: 10/890,178

(22) Filed: Jul. 14, 2004

(30) Foreign Application Priority Data
Mar. 15, 2004 (KR) 2004-17442

(51) Int. Cl. H01L 27/15

(52) U.S. Cl. 257/79; 257/432

(57) ABSTRACT

A high power LED package, in which substantially planar first and second lead frames made of high reflectivity metal are spaced from each other for a predetermined gap. An LED chip is seated on at least one of the lead frames, and having terminals electrically connected to the lead frames, respectively. A package body made of resin seals the LED chip therein while fixedly securing the lead frame in the bottom thereof. The encapsulant preferably fills up the gap between the first and second lead frames. The LED package is structured to raise thermal radiation efficiency thereby reducing the size and thickness thereof.

### CLAIM OF PRIORITY

This application claims the benefit of Korean Patent Application No. 2004-17442 filed on Mar. 15, 2004, in the Korean Intellectual Property Office, the disclosure of which is incorporated herein by reference.

### BACKGROUND OF THE INVENTION

1. Field of the Invention

The present invention relates to a Light Emitting Diode (LED) package, and more particularly, a high power LED package structured to raise thermal radiation efficiency thereby reducing the size and thickness thereof.

2. Description of the Related Art

LEDs are one type of semiconductors, and generate various colors of light when applied with voltage. The color of light generated from each LED is generally determined by chemical ingredients of the LED. The LEDs are continuously increasing in demand since they has various merits such as long lifetime, low drive voltage, excellent initial drive properties, high vibration resistance and high tolerance with respect to repeated power switching compared to lighting devices using filaments.

However, the LEDs also fail to covert electricity into light for 100%, thereby creating a considerable amount of heat. As a consequence, the LEDs adopt metal lead frames to radiate heat to the outside because internal components of the LEDs become stressed owing to their thermal expansion coefficient difference if heat is not properly radiated.

In particular, some LEDs such as high power LEDs are recently adopted in illumination systems and backlight units for large-sized Liquid Crystal Displays (LCDs). Such high power LEDs are required to have superior thermal radiation performance because these systems or units require larger power.

FIG. 1 is a perspective sectional view of a conventional high power LED package. Referring to FIG. 1, the LED package 1 includes an LED chip 2 made of for example an InGaN semiconductor, a thermal radiation member or metal slug 3 for seating the LED chip 2 thereon while functioning as a heat sink, a housing 4 for containing the metal slug 3, a silicone encapsulant 5 for sealing the LED chip 2 and the top of the metal slug 3, a plastic lens 6 for covering the silicon encapsulant 5 and a pair of wires 7 (only one is shown) for supplying voltage to the LED chip 2. In the meantime, the wires 7 are electrically connected with terminals 7. The LED chip 2 is connected to a submount (not shown) via solders, and the submount seats the LED chip 2 on the metal slug 3.

Referring to FIG. 2, the LED package 1 of FIG. 1 is mounted on a mother board 10, and a thermal conductive pad 9 such as a solder is interposed between the metal slug 3 of the LED package 1 and the mother board 10 to facilitate the heat conduction between them.

The LED package 1 and its mounting structure on the mother 10 as shown in FIGS. 1 and 2 are focused to thermal radiation to efficiently radiate heat to the outside. That is, the LED package 1 is so designed that the metal slug 3 as a heat sink is mounted directly or via the thermal conductive pad 9 on the mother board 10 in order to absorb heat generated from the LED chip 2 and radiate heat to the outside. Then, a major quantity of heat from the LED chip 2 is conducted through the metal slug 3 to the mother board 10 and only a minor quantity of heat is radiated to the air through the surface of the LED package 1 including the housing 4 and the lens 6.

Thanks to the these reasons, LED packages of the above structure are widely adopted in the LED field.

However, the above conventional thermal radiation structure of the LED package has a bulky size thereby to obstruct the miniaturization of an illumination system. This structure is also complicated obstructing the automation of LED package production as well as requiring a large number of components to be assembled together thereby to burden manufacture cost.

### SUMMARY OF THE INVENTION

The present invention has been made to solve the foregoing problems of the prior art and it is therefore an object of the present invention to provide a high power LED package capable of raising thermal radiation efficiency in order to reduce the size and thickness thereof.

It is another object of the invention to interpose a silicone submount between lead frames and an LED chip of the above LED package in order to prevent the distortion of the lead frames from being transferred directly to the chip in the final package cutting process, thereby improving the reliability of the LED package.

According to an aspect of the invention for realizing the object, there is provided a Light Emitting Diode (LED) package comprising: substantially planar first and second lead frames made of high reflectivity metal, and spaced from each other for a predetermined gap; an LED chip seated on at least one of the lead frames, and having terminals electrically connected to the lead frames, respectively; and a package body made of resin for sealing the LED chip therein while fixedly securing the lead frame in the bottom thereof.

In the LED package of the invention, the resin preferably fills up the gap between the first and second lead frames.

Preferably, the body may comprise a first resin covering the LED chip and predetermined portions of the lead frames adjacent to the LED chip; and a second resin covering the first resin and remaining portions of the lead frames.

In addition, the LED package of the invention may further comprise a silicon submount placed on the first and second lead frames while seating the LED chip thereon.

### BRIEF DESCRIPTION OF THE DRAWINGS

FIG. 1 is a sectional perspective view illustrating a conventional high power LED package;

FIG. 2 is a sectional view illustrating the high power LED package of FIG. 1 mounted on a mother board;

FIG. 3 is a plan view illustrating a high power LED package according to a first embodiment of the invention;

FIG. 4 is a sectional view illustrating the high power LED package in FIG. 3;

FIG. 5 is a sectional view illustrating a heat conduction process when the high power LED package according to the first embodiment of the invention is mounted on a Printed Circuit Board (PCB);

FIG. 6 is a plan view illustrating a high power LED package according to a second embodiment of the invention;

FIG. 7 is a sectional view illustrating the high power LED package in FIG. 6;

FIG. 8 is a plan view illustrating a high power LED package according to a third embodiment of the invention;

FIG. 9 is a sectional view illustrating the high power LED package in FIG. 8;

FIG. 10 is a plan view illustrating a high power LED package according to a fourth embodiment of the invention;

FIG. 11 is a sectional view illustrating the high power LED package in FIG. 10;

FIG. 12 is a plan view illustrating a high power LED package according to a fifth embodiment of the invention;

FIG. 13 is a sectional view illustrating the high power LED package in FIG. 12;

FIG. 14 is a plan view illustrating a high power LED package according to a sixth embodiment of the invention;

FIG. 15 is a sectional view illustrating the high power LED package in FIG. 14;

FIG. 16 is a plan view illustrating a high power LED package according to a seventh embodiment of the invention;

FIGS. 17 to 20 are process sectional views illustrating a LED package fabrication method of the invention for producing LED packages according to the sixth embodiment of the invention as shown in FIGS. 14 and 15;

FIGS. 21 to 23 are process sectional views illustrating a LED package fabrication method of the invention for producing LED packages according to the seventh embodiment of the invention as shown in FIG. 16; and

FIG. 24 is a sectional view illustrating an LED package according to an eighth embodiment of the invention.

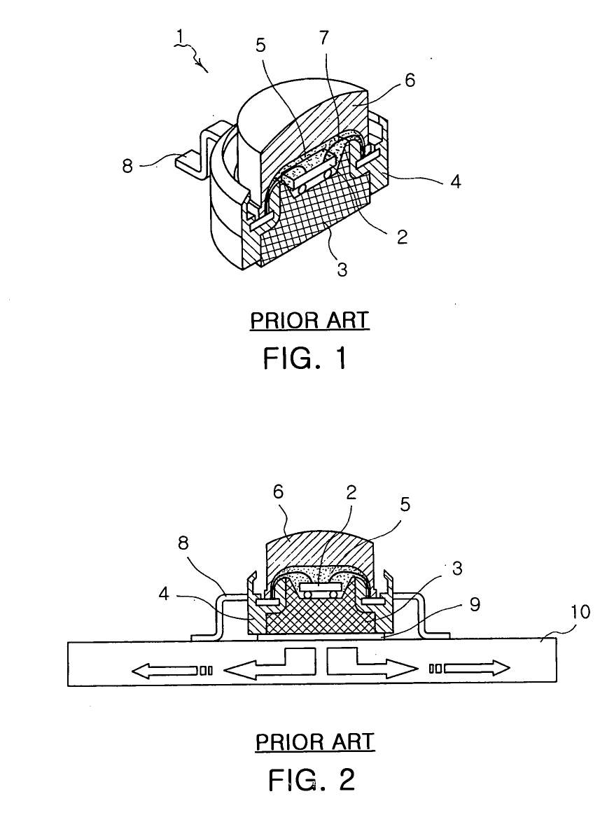

### DETAILED DESCRIPTION OF THE PREFERRED EMBODIMENT

Hereinafter the above and other objects, features and other advantages of the present invention will be more clearly understood from the following detailed description taken in conjunction with the accompanying drawings.

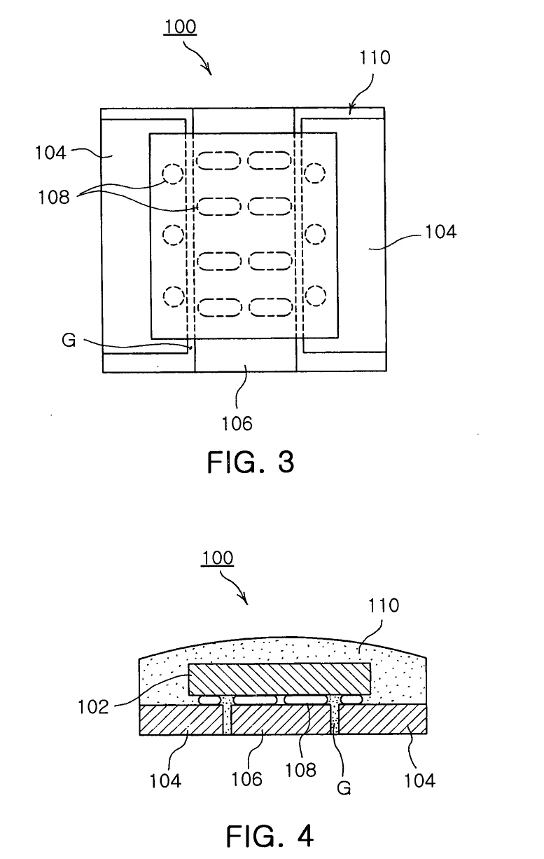

FIG. 3 is a plan view illustrating a high power LED package according to a first embodiment of the invention, and FIG. 4 is a sectional view illustrating the high power LED package in FIG. 3.

Referring to FIGS. 3 and 4, a high power LED package 100 according to the first embodiment of the invention includes a LED chip 102 seated on substantially planar first and second lead frames 104 and 106 spaced apart from each other for predetermined gaps G. A package body 110 made of resin fixedly secures the underlying lead frames 104 and 106 in the bottom thereof while sealing the LED chip 102 therein.

The first lead frames 104 are constituted of two parts that are placed adjacent to both sides of the second lead frame 106 and spaced from the same for the gap G. Both the first and second lead frames 104 and 106 are made of high reflectivity metal to effectively reflect light from the LED chip 102 in an upward direction. The first and second lead frames 104 and 106 are preferably made of Ag or plated or coated with Ag.

One electrode for example a positive pole of the LED 102 is electrically connected with the first lead frame 104 via a group of solder bumps 108, and other electrode for example a negative pole of the LED 102 is electrically connected with the second lead frame 106 via another group of the solder bumps 108.

In the meantime, the first and second lead frames 104 and 106 are attached on the package body 110 of resin and fixedly secured thereby. That is, it is apparent that the first and second lead frames 104 and 106 are maintained in position mainly based upon the coupling with the package body 110 because the first and second lead frames 104 and 106 are only electrically connected with the LED chip 102 via the solder bumps 108, respectively, but spaced from each other for the gap G.

As a result, the package body 110 is preferably made of a resin having strong adhesive force in order to fixedly secure the underlying first and second lead frames 104 and 106 in the bottom thereof while sealing the LED chip 102 therein. In the meantime, the resin of the package body 110 also fills up the gaps G between the first and second lead frames 104 and 106 to impart a substantially planar surface to the entire underside of the LED package 100.

The package body 110 is formed by dispensing resin over the LED chip 102 and the lead frames 104 and 106, and may be formed preferably via transfer molding with a mold to have a uniform convex configuration.

The resin of the package body 110 may be selected from various examples, preferably, which can endure the heat from the LED chip 102 while efficiently transmitting light from the LED to the outside. Also, the resin preferably contains ultraviolet absorbent for preventing the radiation of ultraviolet from the LED chip 102 to the outside and/or fluorescent substance for adjusting color. Furthermore, the resin preferably has chemical and physical properties capable of blocking at least external chemical or physical influences.

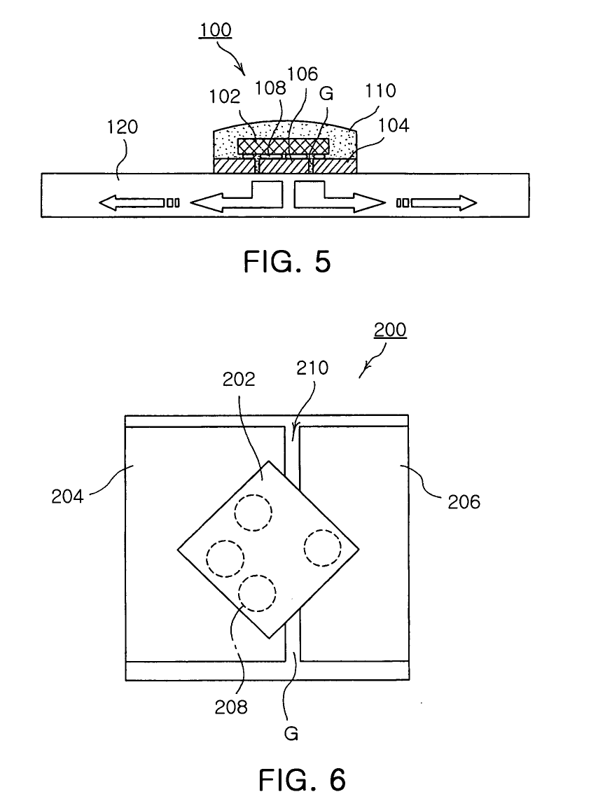

FIG. 5 is a sectional view illustrating a heat conduction process when the high power LED package 100 according to the first embodiment of the invention is mounted on a Printed Circuit Board (PCB) 120. When the LED package 100 of the invention is mounted on the PCB 120 as shown in FIG. 5, the LED package 100 is mounted on the PCB 120 via solder paste (not shown) applied on the surface of the PCB 120. As a consequence, the lead frames 104 and 106 of the LED package 100 contact the PCB 120 in a wider area than a conventional LED package.

This structure has an advantage in that the lead frames 104 and 106 of large areas directly contact the PCB 120 forming a relatively large heat conduction area. Describing this with reference to FIG. 5, as the LED chip 102 emits light generating heat, this heat is transmitted to the PCB 120 via the lead frames 104 and 106 as indicated with arrows in FIG. 5. That is, the lead frames 104 and 106 function not only as a reflector but also as a heat sink and/or a thermal conduction pad. In this case, substantially whole area of the LED chip 102 contacts the lead frames 104 and 106 and substantially the whole area of the lead frames 104 and 106 also contact the PCB 120 to obtain a large heat conduction area so that the heat generated from the LED chip 102 is effectively radiated to the PCB 120 via the lead frames 104 and 106.

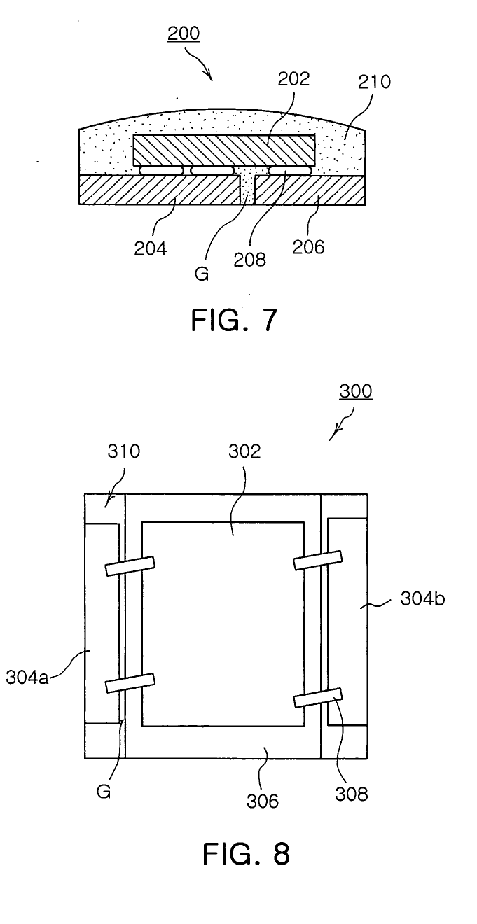

FIG. 6 is a plan view illustrating a high power LED package according to a second embodiment of the invention, and FIG. 7 is a sectional view illustrating the high power LED package in FIG. 6. Referring to FIGS. 6 and 7, an LED package 200 according to the second embodiment of the invention has substantially the same construction as the LED package 100 according to the first embodiment except for the orientation of an LED chip 202 and first and second lead frames 204 and 206. Therefore, the parts having substantially the same function are provided with the same reference numerals, increased by 100, and the description thereof will be substituted by that of the first embodiment.

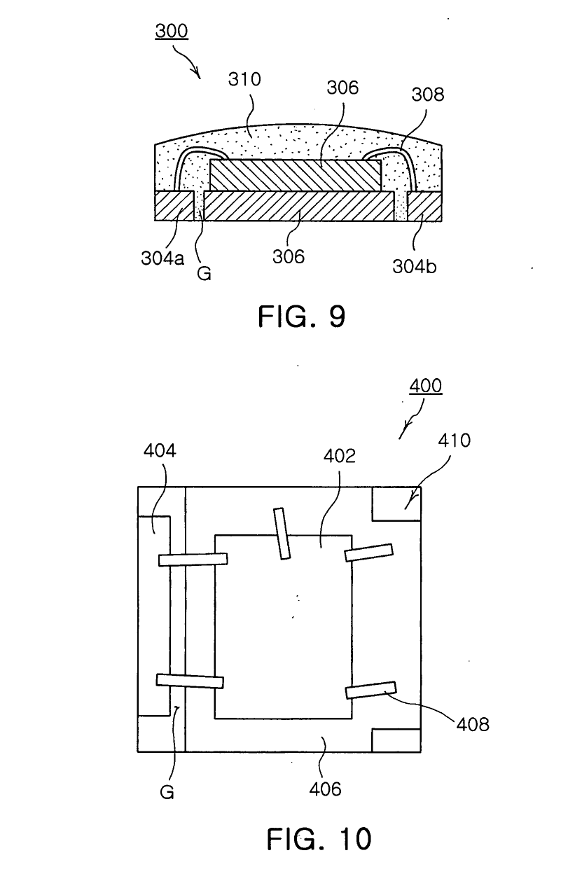

FIG. 8 is a plan view illustrating a high power LED package according to a third embodiment of the invention, and FIG. 9 is a sectional view illustrating the high power LED package in FIG. 8. Referring to FIGS. 8 and 9, an LED package 300 according to the third embodiment of the invention is provided based upon wire bonding that discriminates the LED package 300 from the flip chip type LED packages 100 and 200 according to the first and second embodiments.

That is, the LED chip 302 sated on a reflector 306 has first and second electrodes (not shown) electrically connected to first and second lead frames 304a and 304b via wires 308 (preferably made of Au), and the first and second lead frames 304a and 304b are spaced apart from the reflector 306 for a predetermined gap G.

The first and second lead frames 304a and 304b and the reflector 306 are made of high reflectivity metal to effectively reflect light from an LED chip 302 in an upward direction. Preferably, the first and second lead frames 304a and 304b and the reflector 306 are made of Ag, or coated or plated with Ag.

A package body 310 made of resin fixedly secures the first and second lead frames 304a and 304b and the reflector 306 in the bottom thereof while sealing the LED chip 302 therein. This structure allows the LED chip 302 to be sealed and fixed between the package body 310 and the reflector 306. As a consequence, the package body 310 is preferably made of a resin having strong adhesive force in order to fixedly secure the first and second lead frames 304a and 304b and the reflector 306 in the bottom thereof while sealing the LED chip 302 therein. In the meantime, other features of the resin are substantially the same as those of the first embodiment.

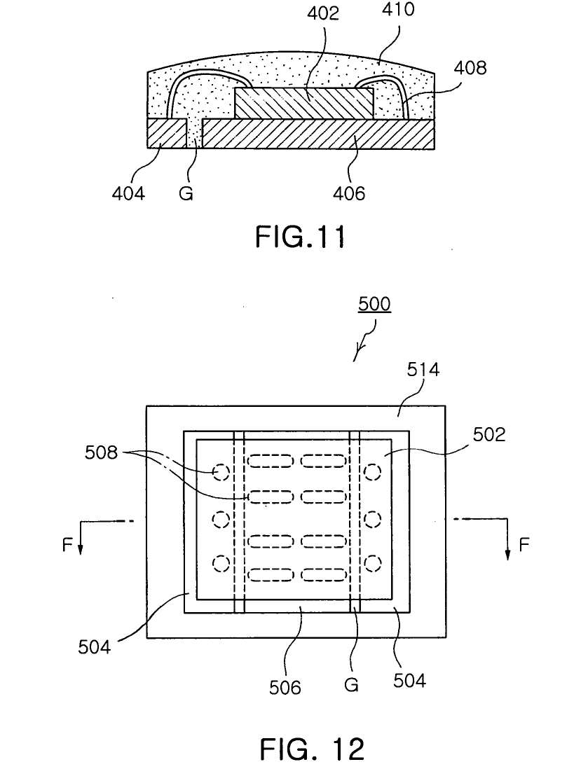

FIG. 10 is a plan view illustrating a high power LED package according to a fourth embodiment of the invention, and FIG. 11 is a sectional view illustrating the high power LED package in FIG. 10. Referring to FIGS. 10 and 11, an LED package 400 according to the fourth embodiment of the invention has substantially the same construction as the LED package 300 according to the third embodiment except that a second lead frame 406 is adapted to seat an LED chip 402 exclusively thereon. Therefore, the parts having substantially the same function are provided with the same reference numerals in the third embodiment, increased by 100, and the description thereof will be substituted by that of the third embodiment together with those of the preceding first and second embodiments.

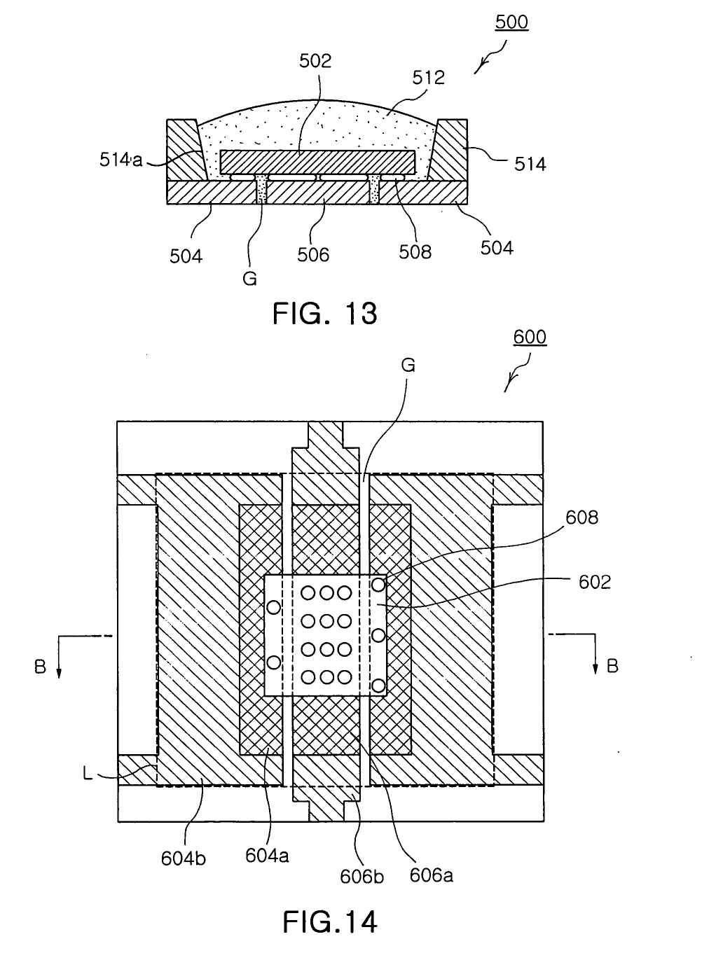

FIG. 12 is a plan view illustrating a high power LED package according to a fifth embodiment of the invention, and FIG. 13 is a sectional view illustrating the high power LED package in FIG. 12. Referring to FIGS. 12 and 13, as technical features discriminated from the LED 100 of the first embodiment, an LED package 500 of the fifth embodiment has a dam 514 having an inclined inside wall 514a on peripheries of first and second lead frames 504 and 506 and a body 510 made of resin within the dam 514. Therefore, the remaining construction is substantially the same as that of the LED package 100, and the parts having substantially the same function are provided with the same reference numerals in 500s.

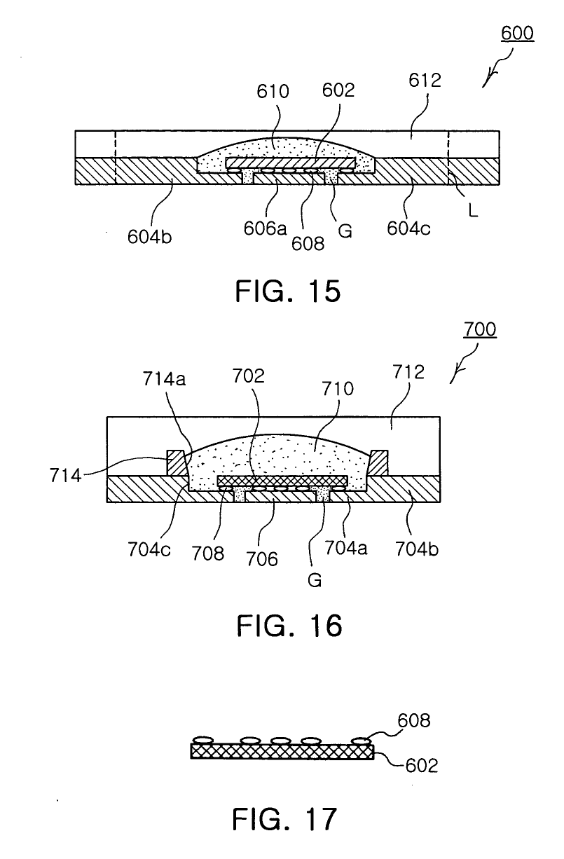

FIG. 14 is a plan view illustrating a high power LED package according to a sixth embodiment of the invention, and FIG. 15 is a sectional view illustrating the high power LED package in FIG. 14. Referring to FIGS. 14 and 15, a high power LED package 600 according the sixth embodiment of the invention includes substantially planar first and second lead frames 604 and 606 spaced apart from each other for a predetermined gap G and an LED chip 602 seated on the lead frames 604 and 606. Each of the first lead frames 604 has a seating section 604a for seating an LED chip 602 thereon, an outer section 604b and a step 604c formed between the seating section 604a and the outer section 604b. The second frame 606 has a seating section 606a, an outer section 606b and steps (not shown) formed between the seating section 606a and the outer section 606b in the same geometry as the steps 604c. Preferably, the outer sections 604b are formed flush with or higher than the LED chip 602 seated on solder bumps 608.

The LED chip 102 is wrapped in an encapsulant 610, which fixedly secures the underlying seating sections 604a and 606a in the bottom thereof. The ecapsulant 610 is formed by dispensing resin such as silicone, and may be formed preferably via transfer molding with a mold to have a uniform convex configuration. The resin of the encapsulant 610 preferably contains ultraviolet absorbent for preventing the radiation of ultraviolet from the LED chip 602 to the outside and/or fluorescent substance for adjusting color. In this case, the resin of the encapsulant 610 also fills up the gaps G between the first and second lead frames 604 and 606 to impart a substantially planar surface to the entire underside of the LED package 600.

The first lead frames 604 are constituted of two parts, which are placed adjacent to both sides 606 of the second lead frame 606 at a predetermined gap G. The first and second lead frames 604 and 606 are made of high reflectivity metal to efficiently reflect light from the LED chip 602 in an upward direction. Preferably, the lead frames 604 and 606 may be made of Ag or plated or coated with Ag. The steps 604c of the first lead frames 604 cooperate with the steps (not shown) of the second lead frame 606 to guide light emitting through the flank of the LED 602 in an upward direction.

In the meantime, one electrode for example a positive electrode of the LED chip 602 is electrically connected to the first lead frames 604 a group of via the solder bumps 608, and the other electrode for example a negative electrode of the LED chip 602 is electrically connected to the second lead frame 606 via another group of the solder bumps 108.

A lens 612 is formed on the top of the silicone encapsulant 610, and made of transparent resin such as epoxy. The lens 612 cooperates with the encapsulant 610 to fixedly secure the first and second lead frames 604 and 606 while protecting the encapsulant 610 from the external environment. That is, because the first and second lead frames 604 and 606 are merely electrically connected to the LED chip 602 via the solder bumps 608 but separated from each other for the gap G, they are mainly maintained in position via the coupling with the encapsulant 610 forming a package body and the lens 612.

As a result, the encapsulant 610 forming the package body and the lens 612 are made of resins preferably having strong adhesive force in order to fixedly secure the underlying first and second lead frames 604 and 606 in the bottom thereof while sealing the LED chip 602 therein.

The resins of the encapsulant 610 and the lens 612 may be selected from various examples, preferably, which can endure the heat from the LED chip 602 while efficiently transmitting light from the LED chip 602 to the outside. Also, the resin of the lens 612 preferably has chemical and physical properties capable of blocking at least external chemical or physical influences.

FIG. 16 is a plan view illustrating a high power LED package according to a seventh embodiment of the invention. As shown in FIG. 16, an LED package 700 of the seventh embodiment has the same construction as the LED 600 of the sixth embodiment except that a dam 714 having an inclined inside wall 714a is placed directly above first frame steps 704c and steps (not shown) of a second frame 706 and an encapsulant 710 made of resin is formed within the dam 714. Therefore, the remaining description of the LED package 700 will be substituted by that of the LED package 600, and the corresponding parts having are provided with the same reference numerals in 700s.

Hereinafter an LED package fabrication method of the invention for obtaining LED packages 600 of the sixth embodiment as shown in FIGS. 14 and 15 will be described with reference to FIGS. 17 to 20.

First, a number of LED chips 602 are prepared, and solder bumps 608 are attached on electrodes as shown in FIG. 17.

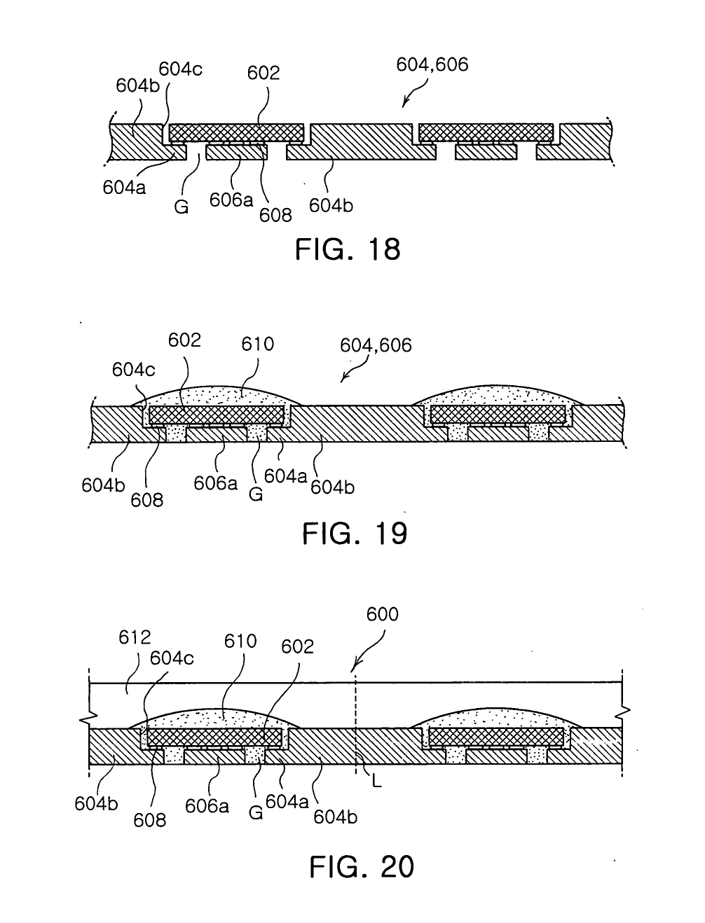

The LED chips 602 with the solder bumps 608 are turned upside down and seated on seating sections 604a and 606a of a lead frame sheet 604, 606, in which a number of first and second lead frames are connected in succession as shown in FIG. 18.

Next encapsulant resin such as silicone is dispensed onto the LED chips 602 and the seating sections 604a and 606a to form encapsulants 610 as shown in FIG. 19. Optionally, transfer molding may be carried out with a mold so that the encapsulants 610 have a uniform convex geometry.

In FIG. 20, a desired resin is applied on the entire structure including the encapsulants 610 and the lead frame sheet 604, 606 and then dried to form an LED sheet structure having connected lenses 612. Then, the LED sheet structure is defleshed and then cut along dotted lines L via for example punching to produce a number of LED packages 600 as shown in FIGS. 14 and 15.

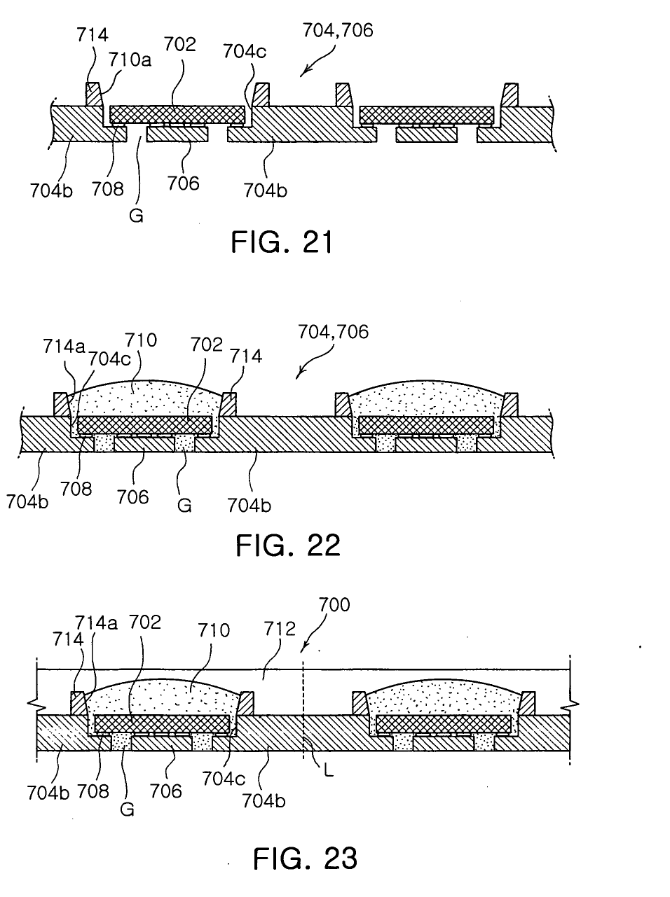

Hereinafter another LED package fabrication method of the invention for obtaining LED packages 700 of the sixth embodiment as shown in FIG. 16 will be described with reference to FIGS. 21 to 23.

The LED package fabrication method shown in FIGS. 21 to 23 is substantially the same as the LED package fabrication method shown in FIGS. 17 to 20 except that a dam 714 having an inclined inside wall 714a is placed directly above first frame steps 704c and steps (not shown) of a second frame 706 and an encapsulant 710 made of resin is formed within the dam 714. Therefore, the remaining description will be substituted by the above description in conjunction with FIGS. 17 to 20, and the corresponding components are provided with the same reference numerals in 700s.

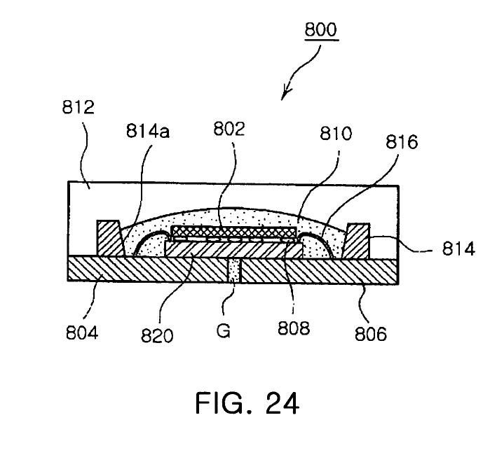

FIG. 24 is a sectional view illustrating an LED package according to an eighth embodiment of the invention. Referring to FIG. 24, an LED package 800 of the eighth embodiment of the invention has substantially planar first and second lead frames 804 and 806 spaced from each other at a predetermined gap G, a silicon submount 820 seated on the first and second lead frames 804 and 806 and an LED chip 802 seated on the silicone submount 820.

The first and second lead frames 804 and 806 are made of high reflectivity metal in order to efficiently reflect light from the LED chip 802 in an upward direction. Preferably, the lead frames 804 and 806 may be made of Ag or plated or coated with Ar.

The silicone submount 820 has metal patterns (not shown) printed thereon, which are coupled with and solder bumps 808 of the LED chip 802 to be electrically connected with the lead frames 804 and 806 via wires 816 (preferably made of Au), respectively. As a consequence, one electrode for example a positive electrode of the LED chip 802 is electrically connected to the first lead frame 804 via the solder bumps 808, some of the metal patterns of the silicone submount 820 and the wires 816. The other electrode for example a negative electrode of the LED chip 802 is electrically connected to the second lead frame 806 in the same way.

The silicone submount 820 has horizontal and vertical sizes larger than the LED chip 802 seated thereon for about 300 to 500 μm, preferably, about 400 μm. In addition, the silicone submount 820 also has a high thermal conductivity for efficiently transmitting heat from the LED chip 802 to the underlying lead frames 804 and 806. The thermal conductivity is preferably 100 W/m·K or more and more preferably 200 W/m·K. For reference, the lead frames typically have a thermal conductivity of about 300 W/m·K.

When the lens sheet structure as shown in FIGS. 20 and 23 are punched into individual LED packages 600 and 700, the distortion of lead frames may be transmitted directly to LED chips potentially damaging the same. The silicone submount 820 prevents this distortion from being directly transmitted the LED chip 802 thereby to improve the reliability of final LED packages 800.

The LED chip 802 is sealed by an encapsulant 810 that fixedly secures the underlying silicone submount 820 on the lead frames 804 and 806. The encapsulant 810 is formed within a dam 814 having an inclined inside wall 814a on peripheries of the first and second lead frames 804 and 806. The dam 814 is made of high reflectivity metal, and preferably Ag. Alternatively, the inclined inside wall 814a may be plated or coated with Ag. The encapsulant is formed by dispensing resin such as silicone, and may be formed via transfer molding in order to have a uniform convex geometry. Hereinafter detailed features of the encapsulant 810 will be substituted by those of the first to seventh embodiments described hereinbefore.

A lens 812 made of transparent resin such as epoxy is formed on the silicone encapsulant 810, and detailed features of the lens 812 will also quote those of the first to seventh embodiments described hereinbefore.

While the LED package 800 of the eighth embodiment has been described to have the flat first and second lead frames 804 and 806, the first and second lead frames may be stepped in to seat the LED chip on seating sections formed therein as in the sixth and seventh embodiments.

As set forth above, the invention can raise the thermal radiation efficiency of the high LED package to reduce the size and thickness thereof. Accordingly, this can simplify a fabrication process and thus improve productivity and save manufacture cost.

Furthermore, the silicone submount is placed between the lead frame and the LED chip in order to prevent the distortion of the lead frames from being transferred directly to the chip in the final package cutting process, thereby improving the reliability of the LED package.

While the present invention has been shown and described in connection with the preferred embodiments, it will be apparent to those skilled in the art that modifications and variations can be made without departing from the spirit and scope of the invention as defined by the appended claims.

1. A Light Emitting Diode (LED) package comprising:
substantially planar first and second lead frames made of high reflectivity metal, and spaced from each other for a predetermined gap;
an LED chip seated on at least one of the lead frames, and having terminals electrically connected to the lead frames, respectively; and
a package body made of resin for sealing the LED chip therein while fixedly securing the lead frame in the bottom thereof.

2. The LED package according to claim 1, wherein the resin fills up the gap between the first and second lead frames.

3. The LED package according to claim 1, wherein the lead frames are stepped up from the center of the LED package having the LED chip seated thereon toward the outer periphery of the LED package.

4. The LED package according to claim 1, wherein the body has a convex top face.

5. The LED package according to claim 1, wherein the body comprises:
a first resin covering the LED chip and predetermined portions of the lead frames adjacent to the LED chip; and
a second resin covering the first resin and remaining portions of the lead frames.

6. The LED package according to claim 1, wherein the first resin has a convex top face.

7. The LED package according to claim 5, wherein the first resin contains at least one of ultraviolet absorbent and fluorescent substance.

8. The LED package according to claim 5, wherein the second resin contains at least one of ultraviolet absorbent and fluorescent substance.

9. The LED package according to claim 5, wherein the first resin is silicon resin.

10. The LED package according to claim 5, wherein the second resin is epoxy resin.

11. The LED package according to claim 1, wherein the resin of the body contains at least one of ultraviolet absorbent and fluorescent substance.

12. The LED package according to claim 1, further comprising a dam placed on the lead frames around the LED chip, and spaced from the LED chip for a predetermined gap.

13. The LED package according to claim 12, wherein the dam is made of high reflectivity metal.

14. The LED package according to claim 12, wherein the dam is made of Ag.

15. The LED package according to claim 1, further comprising a silicon submount placed on the first and second lead frames while seating the LED chip thereon.
